(19) United States
(12) Patent Application Publication
(10) Pub. No.: US 2018/0212092 A1
(43) Pub. Date: Jul. 26, 2018

(54) Adhesive Layer For Printed CIGS Solar Cells

(71) Applicant: Nanoco Technologies Ltd., Manchester (GB)

(72) Inventors: Zugang Liu, Manchester (GB); Stuart Stubbs, Manchester (GB); Stephen Whitelegg, Manchester (GB); Cary Allen, Manchester (GB)

(21) Appl. No.: 15/412,827

(22) Filed: Jan. 23, 2017

(51) Int. Cl. H01L 31/0749; H01L 31/18

(52) U.S. Cl. CPC H01L 31/0749; H01L 31/1864; H01L 31/1872

(57) ABSTRACT

An adhesive layer in a copper indium gallium selenide (CIGS) solar cell is provided between the main CIGS layer and molybdenum film to avoid delamination of the CIGS layer and may also act as an electrical modification to increase the charge collection and power conversion efficiency (PCE) of the device.

### CROSS-REFERENCE TO RELATED APPLICATIONS

This application claims the benefit of U.S. Provisional Application No. 62/299,652, filed on Feb. 25, 2016, the contents of which are hereby incorporated by reference in their entirety.

### STATEMENT REGARDING FEDERALLY SPONSORED RESEARCH OR DEVELOPMENT

Not Applicable

### BACKGROUND OF THE INVENTION

### 1. Field of the Invention

The present invention generally relates to photo-voltaic solar cells. More particularly, it relates to photovoltaic solar cells comprising thin films of copper indium gallium selenide (CIGS).

### 2. Description of the Related Art Including Information Disclosed Under 37 CFR 1.97 and 1.98

A copper indium gallium selenide solar cell (or CIGS cell, sometimes CI(G)S cell) is a thin-film solar cell used to convert sunlight into electric power. It may be manufactured by depositing a thin layer of copper, indium, gallium selenide (or sulfide) on glass or plastic backing, along with electrodes on the front and back to collect current. Because the material has a high absorption coefficient and strongly absorbs sunlight, a much thinner film is required than that of other semiconductor materials.

CIGS is one of three mainstream thin-film PV technologies, the other two being cadmium telluride and amorphous silicon. Like these materials, CIGS layers are thin enough to be flexible, allowing them to be deposited on flexible substrates. However, as all of these technologies normally use high-temperature deposition techniques, the best performance normally comes from cells deposited on glass. Even so, the performance is marginal compared to modern polysilicon-based panels. Advances in low-temperature deposition of CIGS cells have erased much of this performance difference.

CIGS is a I-III-VI₂ compound semiconductor material composed of copper, indium, gallium, and selenium. The material is a solid solution of copper indium selenide (often abbreviated “CIS”) and copper gallium selenide, with a chemical formula of CuInₓGa₍₁₋ₓ₎Se₂, where the value of x can vary from 1 (pure copper indium selenide) to 0 (pure copper gallium selenide). It is a tetrahedrally bonded semiconductor, with the chalcopyrite crystal structure. The bandgap varies continuously with x from about 1.0 eV (for copper indium selenide) to about 1.7 eV (for copper gallium selenide).

CIGS has an exceptionally high absorption coefficient of more than 10⁵/cm for 1.5 eV and higher energy photons. CIGS solar cells with efficiencies around 20% have been claimed by the National Renewable Energy Laboratory (NREL), the Swiss Federal Laboratories for Materials Science and Technology (Empa), and the German Zentrum für Sonnenenergie and Wasserstoff Forschung (ZSW), which is the record to date for any thin film solar cell.

The most common device structure for CIGS solar cells uses soda-lime glass of about of 1-3 millimeters thickness as a substrate, because the glass sheet contains sodium, which has been shown to yield a substantial open-circuit voltage increase, notably through surface and grain boundary defects passivation. However, many companies are also looking at lighter and more flexible substrates such as polyimide or metal foils. A molybdenum (Mo) metal layer is deposited (commonly by sputtering) which serves as the back contact and reflects most unabsorbed light back into the CIGS absorber. Following molybdenum deposition a p-type CIGS absorber layer is grown by one of several unique methods. A thin n-type buffer layer is added on top of the absorber. The buffer is typically cadmium sulfide (CdS) deposited via chemical bath deposition. The buffer is overlaid with a thin, intrinsic zinc oxide layer (i-ZnO) which is capped by a thicker, aluminum-doped ZnO layer. The i-ZnO layer is used to protect the CdS and the absorber layer from sputtering damage while depositing the ZnO:Al window layer, since the latter is usually deposited by DC sputtering, which is known to be a damaging process. The Al-doped ZnO serves as a transparent conducting oxide to collect and move electrons out of the cell while absorbing as little light as possible.

The CuInSe₂-based materials that are of interest for photovoltaic applications include several elements from Groups I, III and VI of the Periodic Table. These semiconductors are especially attractive for solar applications because of their high optical absorption coefficients and versatile optical and electrical characteristics, which can in principle be manipulated and tuned for a specific need in a given device

The most common vacuum-based process is to co-evaporate or co-sputter copper, gallium, and indium onto a substrate at room temperature, then anneal the resulting film with a selenide vapor. An alternative process is to co-evaporate copper, gallium, indium and selenium onto a heated substrate.

A non-vacuum-based alternative process deposits nanoparticles of the precursor materials on the substrate and then sinters them in situ. Electroplating is another low-cost alternative for application of the CIGS layer.

The Se supply and selenization environment is important in determining the properties and quality of the film. When Se is supplied in the gas phase (for example as H₂Se or elemental Se) at high temperatures, the Se becomes incorporated into the film by absorption and subsequent diffusion. During this step, called chalcogenization, complex interactions occur to form a chalcogenide. These interactions include formation of Cu—In—Ga intermetallic alloys, formation of intermediate metal-selenide binary compounds and phase separation of various stoichiometric CIGS compounds. Because of the variety and complexity of the reactions, the properties of the CIGS film can be difficult to control.

The Se source affects the resulting film properties. H₂Se offers the fastest Se incorporation into the absorber; 50 wt. % Se can be achieved in CIGS films at temperatures as low as 400° C. By comparison, elemental Se only achieves full incorporation with reaction temperatures above 500° C. Films formed at lower temperatures from elemental Se were Se deficient, but had multiple phases including metal selenides and various alloys. Use of H₂Se provides the best compositional uniformity and the largest grain sizes. However, H₂Se is highly toxic and is classified as an environmental hazard.

Printable CIGS nanoparticle ink has proved to be a less expensive approach to manufacturing high efficiency and low-cost CIGS solar cells. Printing technology is much less expensive than conventional vacuum technology in producing CIGS films, and printing a device is a way to obtain desired composition profile, required crystallization in a low coat procedure, and high energy conversion efficiency.

In the selenization process, the printed CIGS nanoparticles become crystallized and form a good crystal layer of CIGS to efficiently collect all light, generating high open circuit voltage (V_{oc}), short circuit current (J_{sc}), and fill factor (FF), and hence high power conversion efficiency (PCE).

Due to the high content of carbon in nanoparticles, the grain growth is limited. To overcome this, a low density Mo film may be used as the reservoir to store the carbon residue left during the annealing process.

During the selenization process, a larger crystals layer is formed. If the larger crystals begin to form at the bottom contact with Mo, there is a risk of the CIGS film becoming cracked and/or delaminated.

Sometimes, a sandwich structure of crystal, with a nanoparticle layer sandwiched between top and bottom crystal layers, appears after selenization. This can cause delamination of the CIGS film from the Mo during the subsequent processes such as CdS deposition. This limits the charge collection and the PCE of finished devices. The present invention solves this problem.

### BRIEF SUMMARY OF THE INVENTION

An adhesive layer in a CIGS solar cell provided between the main CIGS layer and molybdenum film has been found to avoid delamination of CIGS and may also act as an electrical modification to increase the charge collection and device PCE.

### BRIEF DESCRIPTION OF THE SEVERAL VIEWS OF THE DRAWING(S)

FIG. 1 is a scanning electron micrograph (SEM) of a sandwich crystal structure of CIGS.

FIG. 2 is a plot of degree of delamination in a printed CIGS layer versus the presence of an adhesion layer according to the invention.

FIG. 3A and FIG. 3B are SEMs showing the cross section of a CIGS layer on a molybdenum substrate with and without an adhesive layer according to the invention, respectively.

FIG. 4A and FIG. 4B are SEM photomicrographs showing different thicknesses of an adhesive layer according to the invention.

FIG. 5 is a plot showing V_{oc}, J_{sc}, fill factor and efficiency of printed CIGS solar cells versus number of adhesive layers according to the invention.

FIG. 6 is a plot showing V_{oc} of printed CIGS solar cells versus various types of adhesive layers according to the invention.

FIG. 7 is a cross-sectional SEM of a printed CIGS solar cell according to the invention showing the adhesive layer.

### DETAILED DESCRIPTION OF THE INVENTION

In solution-processed CIGS devices, though the mechanism of sintering and selenization in an active Se-rich (e.g. either H₂Se or elemental Se) atmosphere is not clear, crystallization starts from the top. During the conversion of sulfide to selenide, crystallization is accompanied by volume expansion.

It is contemplated that the residual carbon left from the evaporation of solvent and the departure of capping agent during the baking process may be pushed into the interface of Mo and CIGS during the crystallization process if there is no reservoir for carbon, and the crystallization will be stopped. That is why, in preferred devices, there is a smaller particle layer between the top crystal and Mo. This is common for solution-processed CIGS films, (see, e.g., Hibberd, C. J., Chassaing, E., Liu, W., Mitzi, D. B., Lincot, D. and Tiwari, a. N. “Non-vacuum methods for formation of Cu(In, Ga)(Se, S)₂ thin film photovoltaic absorbers,” Progress in Photovoltaics: Research and Applications, 2010, 18(6), 434)

Sometimes, for reasons unclear, the crystallization occurs at both the top and the bottom of the CIGS layer. It is contemplated that Na may play a crucial role in this process inasmuch as Na is often incorporated into films to promote grain growth. If this happens, a sandwich crystal structure is formed, with a smaller particle layer between the top and bottom crystals. This also reportedly happens to solution-processed CZTS films. The reason for this may be related to the carbon residue, which could not escape due to the formation of the bottom crystal. This may cause delimitation, and makes charge collection difficult.

Even if the crystallization starts only on top, when the crystal is thick enough to reach to the back contact with Mo, the risk of cracking and peeling of the CIGS film is high in certain solution-processed CIGS devices.

Applicants have tried to resolve this situation by applying a different density of Mo, adding O₂ in the Mo layer, and by increasing the CIGS thickness. However, none of these techniques has been found to produce both high yield and high PCE.

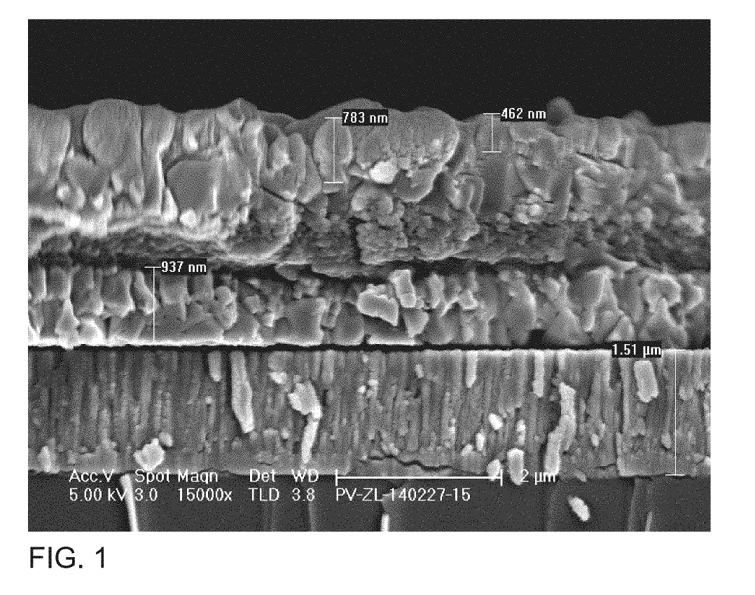

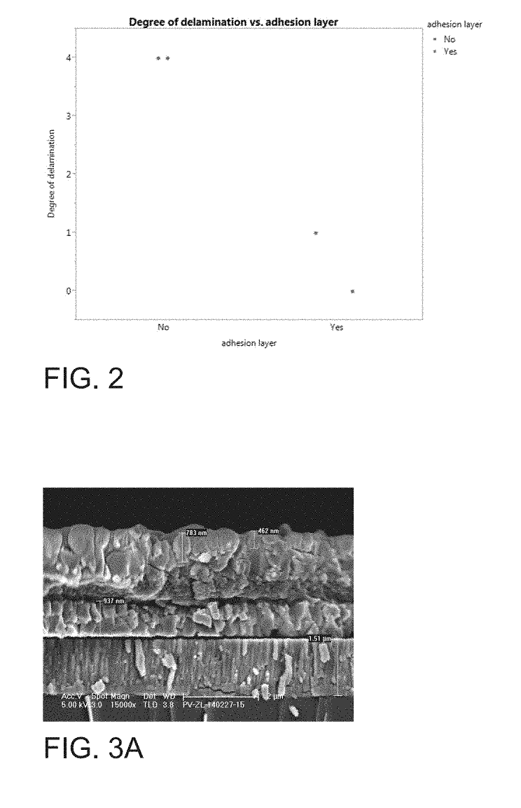

FIG. 1 is an SEM of a sandwich crystal structure of CIGS. It can be seen that, between the top and bottom crystal layers, there is a layer that consists of smaller particles. There is also clear delamination apparent of the bottom crystal layer from the molybdenum layer.

Further investigation has shown that the main reason for delamination of CIGS on molybdenum is that the crystallization reaches the Mo contact, either the whole crystal layer of CIGS or the bottom crystallization. Applicants have discovered that this may be resolved by adding an adhesive layer between the bulk CIGS and Mo to form a thin, non-crystal layer between the crystallized bulk CIGS and Mo. This not only increases the adhesion of CIGS to Mo but also increases the charge collection.

Using a CIGS nanoparticle with less Cu, either with the same Ga content or an even higher Ga content for back Ga gradient, has been found to eliminate delamination and increase device performance.

An exemplary process according to the invention comprises the following steps:

1. Deposit a layer of adhesive on a Mo-coated SLG substrate and anneal to remove the solvent and capping agent. In preferred embodiments, the thickness of the adhesive layer is between about 50 nm and about 200 nm after baking. The said adhesive layer may be coated from inks of CIGS with lower copper content (CGI, copper over gallium plus indium), with same GGI (gallium over gallium plus indium), or higher GGI for back gallium gradient.

2. Deposit on top of the aforesaid adhesive layer, a standard high-CGI CIGS nanoparticle layer, and bake at a suitable temperature (450° C. for example) for between about 0.2-1 minute to form a smooth film. The high-CGI CIGS is chosen for the bulk CIGS layer to enable good crystallization for better light harvesting and high J_{sc} (short circuit current).

3. Repeat the previous step to reach the desired CIGS thickness, for example between 1 and 2 micrometers.

4. Etch with KCN to remove extra copper and possibly the carbon residue and doping potassium.

5. Selenize the films in a reactive Se-containing atmosphere to convert into CIGSe; sinter the CIGSe film; and, crystallize the CIGSe film.

6. Deposit CdS using a suitable deposition technique such as chemical bath deposition to form a p-n junction.

7. Deposit iZnO/ITO/Ni/Aluminum buffer layers and contacts.

This invention provides a solution to the above-described CIGS nanoparticle ink delamination problem with the following advantages:
1. Provides a smaller-grained layer of CIGS between the CIGS crystal and Mo;
2. Eliminates the delamination of a CIGS film on a back contact Mo film; and,
3. Eliminates the bottom crystallization, and enhances the top crystallization, which leads to an increase in charge collection.

Experimental results have shown that the use of a CGI CIGS adhesive layer according to the invention results in the elimination of delamination in printed CIGS solar cells and improved device performance.

TABLE 1

| Device ID | V_{oc} | J_{sc} | FF | PCE | Adhesive layer |
|---|---|---|---|---|---|
| Device 1 | 0.57 | 27.31 | 51.79 | 8.06 | NO |
| Device 2 | 0.60 | 29.47 | 57.10 | 10.00 | YES |

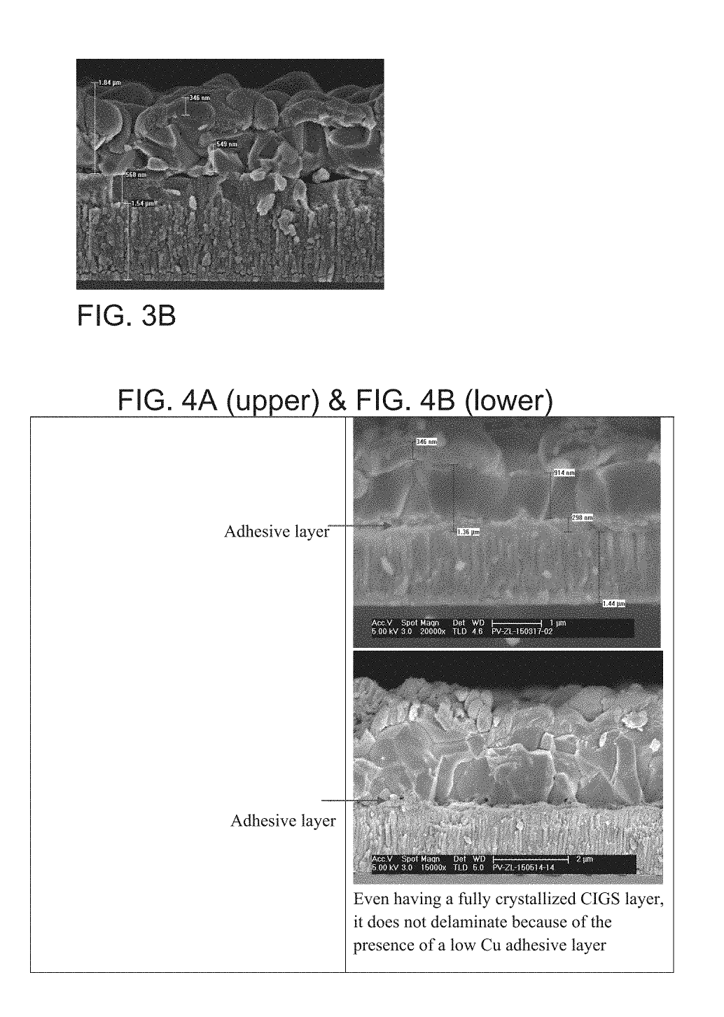

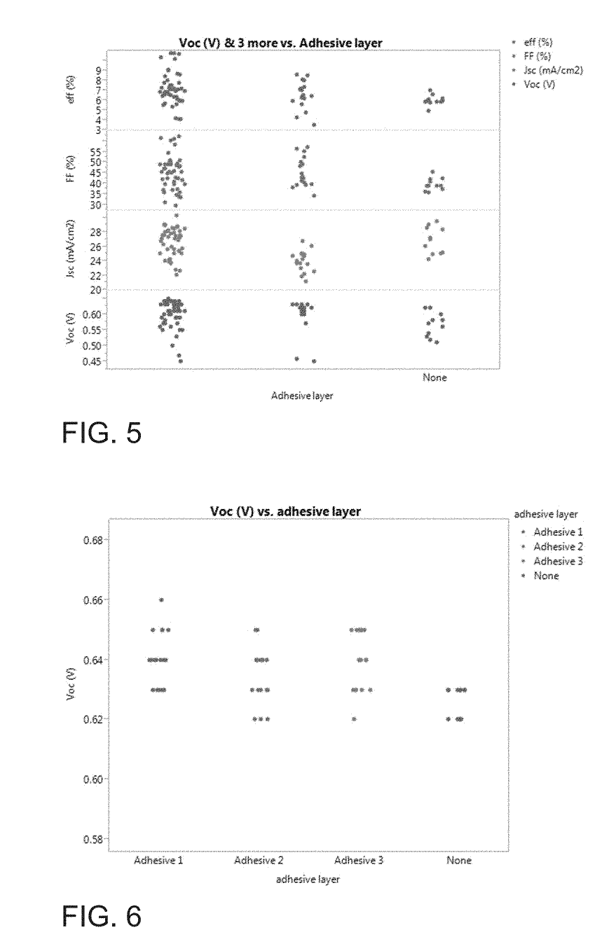

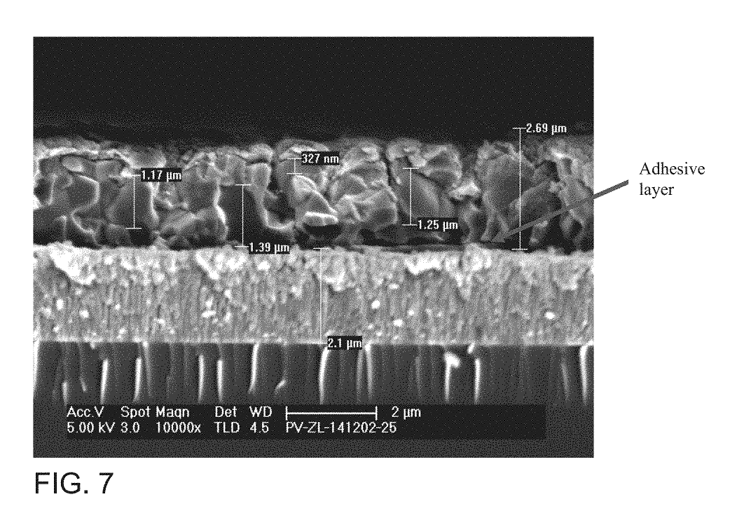

As may be seen in FIGS. 3A and 3B, an interface modification layer according to the invention improves the interface of the CIGS and the molybdenum. FIG. 3A shows a cross section SEM of CIGS on Mo without an adhesive layer. The sandwich crystal structure and clear interface and delamination the Mo and CIGS is readily apparent. FIG. 3B shows a cross section SEM of CIGS on Mo with an adhesive layer according to the invention. Only a top crystal layer is seen and no clear interface between layers and no delamination of the Mo and CIGS is apparent.

FIGS. 4A and 4B show different thicknesses of an adhesive layer according to the invention in a CIGS layer comprising nanoparticles having associated octanethiol and/or tert-nonylmercaptan ligands and a particle size between about 100 and about 150 nm. One or two layers of a CIGS layer has been found to improve the device performance. In the images shown, each CIGS layer is about 150 nm in thickness. A single CIGS layer has been found to provide the best device performance.

For the adhesion layer, it has been found that the Cu/(In+Ga) ratio should preferably be low (<1), and there should be no doping with antimony (Sb).

The foregoing presents particular embodiments of a system embodying the principles of the invention. Those skilled in the art will be able to devise alternatives and variations which, even if not explicitly disclosed herein, embody those principles and are thus within the scope of the invention. Although particular embodiments of the present invention have been shown and described, they are not intended to limit what this patent covers. One skilled in the art will understand that various changes and modifications may be made without departing from the scope of the present invention as literally and equivalently covered by the following claims.

What is claimed is:

1. A printed CIGS solar cell comprising:
a main CIGS layer;
a molybdenum film layer; and,
an adhesive layer between the main CIGS layer and the molybdenum film layer.

2. The printed CIGS solar cell recited in claim 1 wherein the adhesive layer comprises copper, gallium and indium.

3. The printed CIGS solar cell recited in claim 2 wherein the ratio of copper to the sum of indium and gallium in the adhesive layer is less than 1.

4. The printed CIGS solar cell recited in claim 2 wherein the adhesive layer is not doped with antimony.

5. A method for forming a printed CIGS solar cell comprising the steps of:
depositing a layer of adhesive on a Mo-coated soda lime glass substrate;
and annealing to remove solvent and a capping agent;
depositing on top of the aforesaid adhesive layer, a standard high-CGI CIGS nanoparticle layer;
baking at a suitable temperature) for between about 0.2-1 minute to form a smooth film;
repeating the previous step to reach a desired CIGS thickness;
etching with KCN;
selenizing the films in a reactive Se-containing atmosphere to convert into CIGSe;
sintering the CIGSe film;
crystallizing the CIGSe film;
depositing CdS using a suitable deposition technique to form a p-n junction; and,
depositing window layers, buffer layers and electrical contacts.
